(19) United States
(12) Patent Application Publication
(10) Pub. No.: US 2025/0147728 A1
(43) Pub. Date: May 8, 2025

(54) MEMORY DEVICE PERFORMING PROCESSING IN MEMORY AND METHOD OF PERFORMING PROCESSING IN MEMORY THEREOF

(71) Applicant: Samsung Electronics Co., Ltd., Suwon-si (KR)

(72) Inventors: JAEWON PARK, Suwon-si (KR); SHINHAENG KANG, Suwon-si (KR); KYOMIN SOHN, Suwon-si (KR)

(21) Appl. No.: 18/668,411

(22) Filed: May 20, 2024

(30) Foreign Application Priority Data
Nov. 6, 2023 (KR) 10-2023-0151762

(51) Int. Cl. G06F 7/544; G06F 7/501

(52) U.S. Cl. CPC G06F 7/5443; G06F 7/501

(57) ABSTRACT

A memory device includes a memory cell array; and a processing in memory (PIM) unit including a plurality of multiplication and accumulation (MAC) operators which is configured to perform multiply-accumulation operations based on data stored in the memory cell array. The plurality of MAC operators performs the multiply-accumulation operations based on the data in a first stage, and to perform partial sum operations based on result values of the multiply-accumulation operations in a second stage.

### CROSS-REFERENCE TO RELATED APPLICATION

This application claims priority under 35 U.S.C. § 119 to Korean Patent Application No. 10-2023-0151762 filed on Nov. 6, 2023, in the Korean Intellectual Property Office, the disclosure of which is incorporated by reference herein in its entirety.

### BACKGROUND

### 1. Field

Example embodiments of the present disclosure described herein relate to a semiconductor memory device, and more particularly, relate to a memory device configured to perform processing in memory and a method of performing processing in memory thereof.

### 2. Description of Related Art

A semiconductor memory device may be classified as a volatile memory device or a non-volatile memory device. Read and write speeds of a volatile memory device (for example, a DRAM or an SRAM) are generally fast, but the data stored in the volatile memory device are lost when power is turned off or lost. In contrast, a non-volatile memory device may retain data even when the power is turned off or lost. Therefore, a non-volatile memory device may be used to store content that must be preserved regardless of whether power is supplied.

A representative example of the volatile memory device is a random access memory (RAM). It is called processing in memory (PIM) that the RAM directly performs some of operations of a central processing unit (CPU). As the RAM performs some operations directly, an amount of communication between the CPU and the RAM may be reduced and bottleneck phenomenon may be solved. However, due to space limitation of the RAM, all of operators necessary to directly perform operations may not be included in the RAM.

### SUMMARY

Example embodiments of the present disclosure provide a memory device configured to perform MAC operations and partial sum operations using a plurality of MAC operators included in a PIM unit, and a method of performing processing in memory thereof.

According to example embodiments, the memory device includes: a memory cell array; and a processing in memory (PIM) unit including a plurality of multiplication and accumulation (MAC) operators which is configured to perform multiply-accumulation operations based on data stored in the memory cell array. The plurality of MAC operators is configured to perform the multiply-accumulation operations based on the data in a first stage, and to perform partial sum operations based on result values of the multiply-accumulation operations in a second stage.

According to example embodiments, a method of performing processing in memory of a memory device, the method includes: setting up one or more processing in memory (PIM) instructions; loading first data for a PIM operation from a memory cell array of the memory device based on the one or more PIM instructions; and performing the PIM operation based on the first data. The performing the PIM operation includes: performing multiply-accumulation operations on the first data through a plurality of MAC operators in a first stage; and performing partial sum operations based on result values of the multiply-accumulation operations in a second stage when the multiply-accumulation operations are completed.

According to example embodiments, a memory device includes: a memory cell array; control logic configured to control input and output of data to and from, respectively, the memory cell array; and a plurality of MAC operators configured to perform multiply-accumulation operations based on data stored in the memory cell array responsive to a MAC operation start signal received from the control logic. Each of the plurality of MAC operators includes: a multiplier configured to perform a multiplication operation using a first MAC input and a second MAC input as operands; a first multiplexer configured to output a first operation result of the multiplier or a first partial sum input based on a stage information signal; a second multiplexer configured to output a second partial sum input or data stored in an accumulation register based on the stage information signal; and an adder configured to perform an addition operation on a first output of the first multiplexer and a second output of the second multiplexer.

### BRIEF DESCRIPTION OF THE FIGURES

The above and other objects and features of the present disclosure will become apparent by describing in detail embodiments thereof with reference to the accompanying drawings.

FIG. 1 is a block diagram illustrating a memory system according to an example embodiment.

FIG. 2 is a block diagram illustrating a memory device of FIG. 1.

FIG. 3 is a diagram illustrating a processing in memory (PIM) unit of FIG. 2.

FIG. 4 is a diagram illustrating an example embodiment of a PIM execution unit of FIG. 3.

FIG. 5 is a diagram illustrating a general PIM operator.

FIG. 6 is a diagram illustrating an example embodiment of a PIM operator of FIG. 4.

FIG. 7 is a diagram illustrating an example embodiment of a stage manager of FIG. 6.

FIG. 8 is a diagram illustrating an operation of a plurality of MAC operators in FIG. 6 during a MAC stage according to an example embodiment.

FIG. 9 is a diagram illustrating an operation during a partial sum stage of a plurality of MAC operators of FIG. 6 according to an example embodiment.

FIG. 10 is a diagram illustrating one of a plurality of MAC operators in FIG. 6 according to an example embodiment.

FIG. 11 is a flowchart illustrating a PIM operation of a PIM unit of FIG. 2 according to an example embodiment.

FIG. 12 is a flowchart illustrating a method of performing a PIM operation of FIG. 11 according to an example embodiment.

FIG. 13 is a diagram illustrating an example embodiment of a wiring layout of a plurality of MAC operators in FIG. 6.

FIG. 14 is a diagram illustrating another example embodiment of a wiring layout of a plurality of MAC operators in FIG. 6.

FIG. 15 is a diagram illustrating another example embodiment of a wiring layout of a plurality of MAC operators in FIG. 6.

### DETAILED DESCRIPTION

Hereinafter, embodiments of the inventive concept are described in detail with reference to the accompanying drawings. Identical reference numerals are used for the same constituent elements in the drawings, and duplicate descriptions thereof are omitted. As used herein, the term “and/or” includes any and all combinations of one or more of the associated listed items. It is noted that aspects described with respect to one embodiment may be incorporated in different embodiments although not specifically described relative thereto. That is, all embodiments and/or features of any embodiments can be combined in any way and/or combination.

Below, a DRAM will be used as an example for illustrating features and functions of the present disclosure. However, other features and operational performance may be easily understood from information disclosed herein by a person of ordinary skill in the art. The present disclosure may be implemented by other embodiments or applied thereto. Further, the detailed description may be modified or changed according to viewpoints and applications without escaping from the scope, spirit, and other objects of the present disclosure.

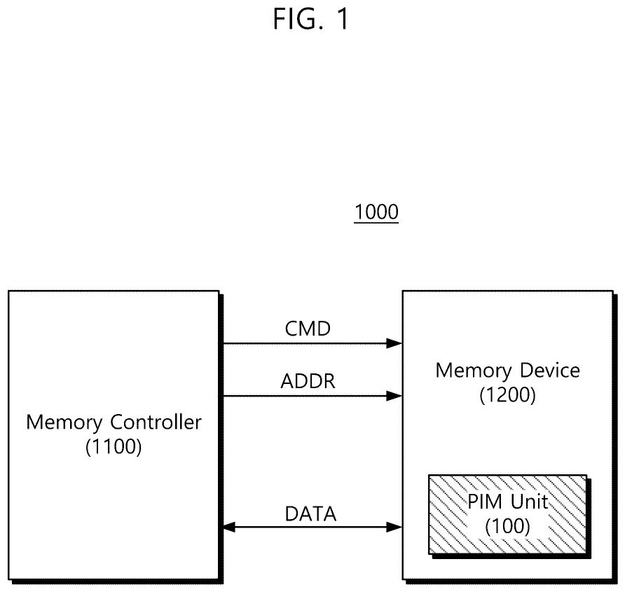

FIG. 1 is a block diagram illustrating a memory system according to an example embodiment. Referring to FIG. 1, a memory system 1000 may include a memory controller 1100 and a memory device 1200.

According to an example embodiment, the memory controller 1100 may perform an access operation of writing data to the memory device 1200 or reading data stored in the memory device 1200. For example, the memory controller 1100 may generate a command CMD and an address ADDR for writing data to the memory device 1200 or reading data stored in the memory device 1200. The memory controller 1100 may include a control circuit for controlling the memory device 1200, a system-on-chip (SoC), such as an application processor (AP), a central processing unit (CPU), a digital signal processor (DSP), and/or a graphics processing unit (GPU).

According to an example embodiment, the memory controller 1100 may provide various signals to the memory device 1200 to control an overall operation of the memory device 1200. For example, the memory controller 1100 may control memory access operations of the memory device 1200 such as a read operation and a write operation. The memory controller 1100 may provide the command CMD and the address ADDR to the memory device 1200 to write data DATA in the memory device 1200 or to read data DATA from the memory device 1200.

According to an example embodiment, the memory controller 1100 may generate various types of commands CMD to control the memory device 1200. For example, the memory controller 1100 may generate a bank request corresponding to a bank operation of changing a state of a memory bank, among a plurality of memory banks, to read or write data DATA. As an example, the bank request may include an active request for changing a state of a memory bank, among the plurality of memory banks, to an active state. The memory device 1200 may activate a row included in the memory bank, for example, a wordline, in response to the active request. The bank request may include a precharge request for changing the memory banks from an active state to a standby state after reading or writing of data DATA is completed. In addition, the memory controller 1100 may generate an input/output (I/O) request (for example, a column address strobe (CAS) request) for the memory device 1200 to perform a read operation or a write operation of data DATA. As an example, the I/O request may include a read request for reading data DATA from activated memory banks. The I/O request may include a write request for writing data DATA in the activated memory banks. The memory controller 1100 may generate a refresh command to control a refresh operation on the memory banks. However, the types of commands CMD described herein are merely examples, and other types of commands CMD may be used.

According to an example embodiment, the memory device 1200 may output data DATA, requested to be read by the memory controller 1100, to the memory controller 1100 or may store data DATA, requested to be written by the memory controller 1100, in a memory cell of the memory device 1200. The memory device 1200 may input and output data DATA based on the command CMD and the address ADDR. The memory device 1200 may include memory banks.

The memory device 1200 may be a volatile memory device, such as a dynamic random access memory (DRAM), a synchronous dynamic random access memory (SDRAM), a double data rate (DDR) DRAM, a DDR SDRAM, a low-power double data rate (LPDDR) SDRAM, a graphics double data rate (GDDR) SDRAM, a Rambus dynamic random access memory (RDRAM), and a static random access memory (SRAM), or the like. In other embodiments, the memory device 1200 may be implemented as a nonvolatile memory device, such as a resistive RAM (RRAM), a phase change memory (PRAM), a magnetoresistive memory (MRAM), a ferroelectric memory (FRAM), a spin-transfer torque RAM (STT-RAM), or the like. In the present specification, the advantages of the present disclosure have been described with respect to a DRAM, but example embodiments are not limited thereto.

According to an example embodiment, the memory banks may include a memory cell array divided in units of banks, a row decoder, a column decoder, a sense amplifier, a write driver, or the like. The memory banks may store data DATA, requested to be written in the memory device 1200, through the write driver and may read data DATA, requested to be read, using the sense amplifier. The memory banks may further include a component for a refresh operation of storing and maintaining data in the cell array, or select circuits based on an address.

According to an example embodiment, the memory device 1200 may include a processing in memory (PIM) unit 100 (hereinafter referred to as the PIM unit 100). The PIM unit 100 may perform a specified operation on data DATA stored in the memory device 1200. The memory device 1200 may store an operation result back in memory banks or transmit the operation result to the memory controller 1100. The PIM unit 100 may perform a specified operation on data DATA received from the memory controller 1100 and transmit an operation result to the memory banks.

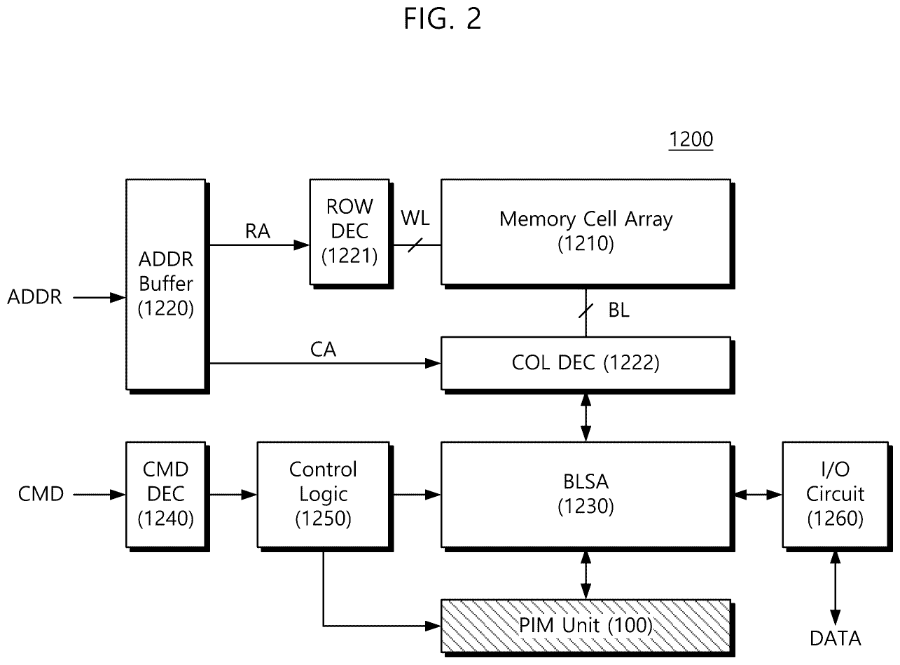

FIG. 2 is a block diagram illustrating a memory device of FIG. 1. Referring to FIG. 2, the memory device 1200 may include a memory cell array 1210, an address buffer 1220, a row decoder 1221, a column decoder 1222, a bitline sense amplifier 1230, a command decoder 1240, control logic 1250 and an input/output circuit 1260. In addition, the memory device 1200 may include a PIM unit 100.

According to an example embodiment, the memory cell array 1210 may include a plurality of memory cells arranged in a matrix of rows and columns. For example, the memory cell array 1210 may include a plurality of wordlines WL and a plurality of bitlines BL connected to memory cells. The plurality of wordlines WL may be connected to rows of the memory cells, and the plurality of bitlines BL may be connected to columns of the memory cells.

According to an example embodiment, the address buffer 1220 may receive an address ADDR from the memory controller 1100 of FIG. 1. For example, the address ADDR may include a row address RA addressing a row of the memory cell array 1210 and a column address CA addressing a column of the memory cell array 1210. The address buffer 1220 may transmit the row address RA to the row decoder 1221 and may transmit the column address CA to the column decoder 1222.

According to an example embodiment, the row decoder 1221 may select one of the plurality of wordlines WL connected to the memory cell array 1210. The row decoder 1221 may decode the row address RA, received from the address buffer 1220, to select a single wordline corresponding to the row address RA and may activate the selected wordline.

According to an example embodiment, the column decoder 1222 may select a predetermined bitline from among the plurality of bitlines BL of the memory cell array 1210. The column decoder 1222 may decode the column address CA, received from the address buffer 1220, to select the predetermined bitline BL corresponding to the column address CA.

According to an example embodiment, the bitline sense amplifier 1230 may be connected to the bitlines BL of the memory cell array 1210. For example, the bitline sense amplifier 1230 may sense a change in voltage of a selected bitline, among the plurality of bitlines BL, and may amplify and output the change in voltage.

According to an example embodiment, the command decoder 1240 may decode a write enable signal/WE, a row address strobe signal/RAS, a column address strobe signal/CAS, and a chip select signal/CS received from the memory controller 1100, such that control signals corresponding to the command CMD are generated in the control logic 1250. The command CMD may include an active request, a read request, a write request, or a precharge request.

According to an example embodiment, the control logic 1250 may control an overall operation of the bitline sense amplifier 1230 and the PIM unit 100 through the control signals corresponding to the command CMD. Additionally, the control logic 1250 may control an overall operation of the memory device 1200.

According to an example embodiment, the input/output circuit 1260 may output data DATA to the memory controller 1100 through a data pad based on a sensed and amplified voltage from the bitline sense amplifier 1230. For example, the input/output circuit 1260 may include an input buffer or an output buffer. The input buffer or the output buffer may be electrically connected to the data pad. The input/output circuit 1260 may perform a serialization operation or a deserialization operation of data DATA.

According to an example embodiment, the PIM unit 100 may perform a specified operation on data DATA stored in the memory cell array 1210. An operation result may be stored again in the memory cell array 1210 or output through the input/output circuit 1260. The PIM unit 100 may perform a specified operation on data DATA received from the input/output circuit 1260 and transmit an operation result to the memory cell array 1210.

According to an example embodiment, the PIM unit 100 may include a plurality of multiplication and accumulation (MAC) operators (hereinafter referred to as a MAC operator). For example, the PIM unit 100 may perform a MAC operation through a plurality of MAC operators. Additionally, the PIM unit 100 may perform a partial sum operation through adders included in a plurality of MAC operators. Accordingly, additional space for adders may be saved, and the memory device 1200 may efficiently perform MAC operations in the same area.

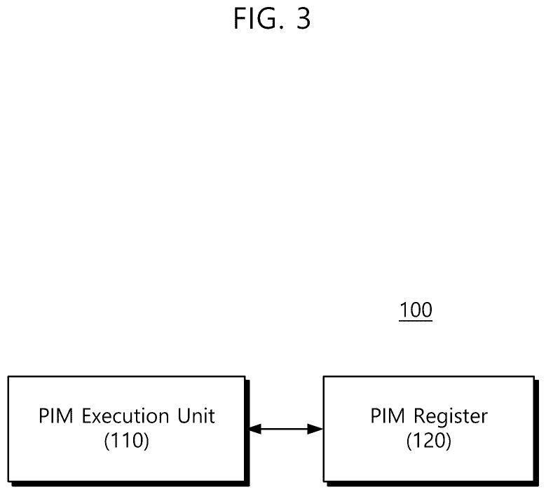

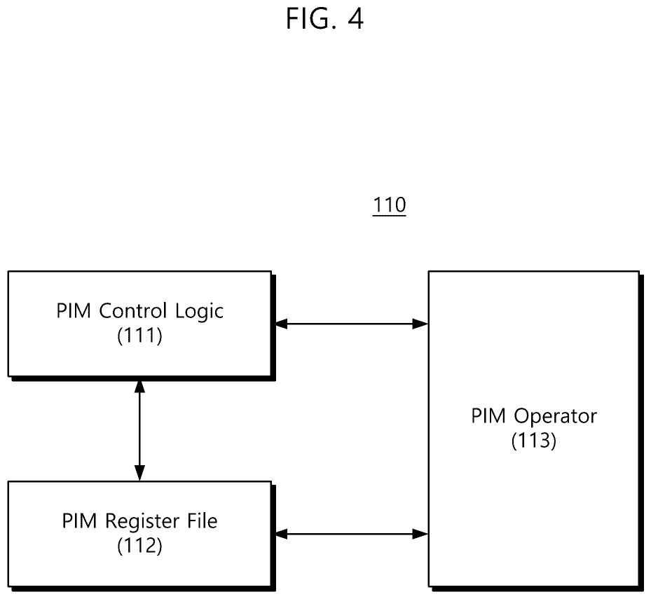

FIG. 3 is a diagram illustrating a PIM unit of FIG. 2. FIG. 4 is a diagram illustrating an example embodiment of a PIM execution unit of FIG. 3. Referring to FIGS. 2 to 4, the PIM unit 100 may include a PIM execution unit 110 and a PIM register 120. The PIM execution unit 110 may include a PIM control logic 111, a PIM register file 112, and a PIM operator 113.

According to an example embodiment, the PIM execution unit 110 may perform a PIM operation under the control of the control logic 1250 of FIG. 2. For example, the PIM execution unit 110 may receive first data from the memory cell array 1210. The PIM execution unit 110 may receive second data from the PIM register 120. The PIM execution unit 110 may perform an operation based on the first data and the second data and output result data. As an example, the PIM execution unit 110 may include a single instruction multiple data (SIMD) floating-point unit (FPU).

According to an example embodiment, the PIM execution unit 110 may store the result data in the memory cell array 1210 through the bit line sense amplifier 1230. In other embodiments, the PIM execution unit 110 may store the result data in the PIM register 120. The PIM execution unit 110 may repeatedly perform operations based on the result data stored in the PIM register 120. The result data stored in the PIM register 120 may be transmitted to the memory controller 1100 through the input/output circuit 1260.

According to an example embodiment, the PIM control logic 111 may control an overall operation of the PIM operator 113 according to the control of the control logic 1250 of FIG. 2. The PIM register file 112 may include a plurality of registers. The PIM register file 112 may store a plurality of data to be used in the PIM operator 113. The PIM register file 112 may store data received from the memory cell array 1210. The PIM register file 112 may store result data output from the PIM operator 113.

According to an example embodiment, the PIM operator 113 may perform a PIM operation under the control of the PIM control logic 111. For example, the PIM operator 113 may receive first data from the memory cell array 1210. The PIM operator 113 may receive second data from the PIM register file 112. The PIM operator 113 may perform an operation based on the first data and the second data, and the PIM operator 113 may output result data.

According to an example embodiment, the PIM operator 113 may include a plurality of MAC operators. Each of the plurality of MAC operators may include a multiplier, an adder, and an accumulation register. The PIM operator 113 may perform MAC operations through a plurality of MAC operators. Additionally, the PIM operator 113 may perform partial sum operations through adders included in a plurality of MAC operators.

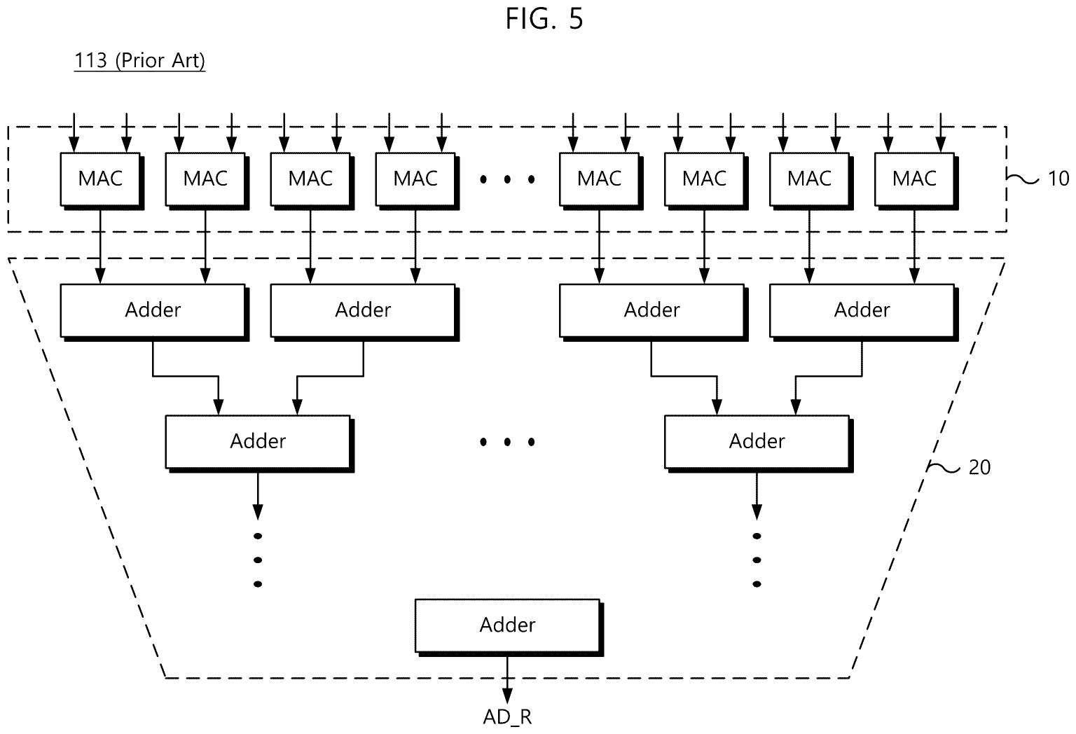

FIG. 5 is a diagram illustrating a general PIM operator. Referring to FIG. 5, the PIM operator 113 may include a plurality of MAC operators 10 and an adder tree 20. The adder tree 20 may include a plurality of adders.

Each of the plurality of MAC operators 10 may receive two input values. Each of the plurality of MAC operators 10 may perform a MAC operation on the input values and output one result value. Result values of the plurality of MAC operators 10 may be input values of the adder tree 20. The adder tree 20 may perform partial sum operations of the result values of the plurality of MAC operators 10.

Each of the plurality of adders included in the adder tree 20 may add two input values and output one result value. Adders placed at the top of the adder tree 20 may receive the result values from a plurality of MAC operators 10 and output result values. The result values of the adders placed at the top of the adder tree 20 may be input values of adders of the next level in the adder tree 20. By repeating this, one adder placed at the bottom of the adder tree 20 may finally output one adder tree result AD_R.

The adder tree 20 may occupy the same or similar area as the plurality of MAC operators 10. Therefore, in the case of the memory device 1200 with a limited area, the adder tree 20 may be omitted or only partially included. In other embodiments, the partial sum operation of the adder tree 20 may be performed in the host. However, if the PIM operator 113 cannot perform the partial sum operation, the performance of the PIM unit 100 may be limited.

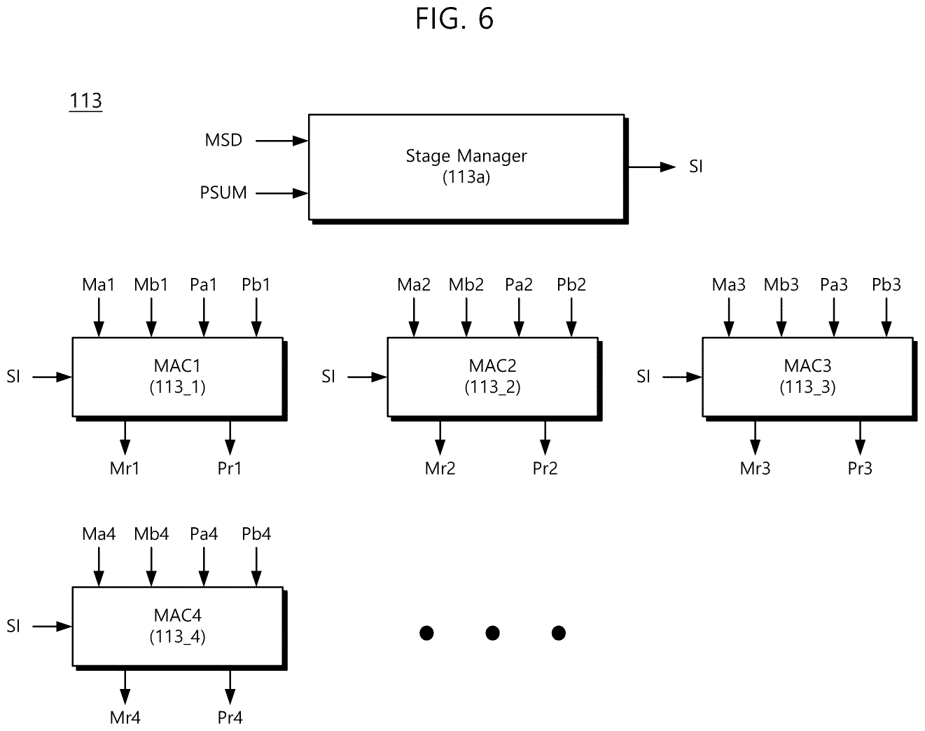

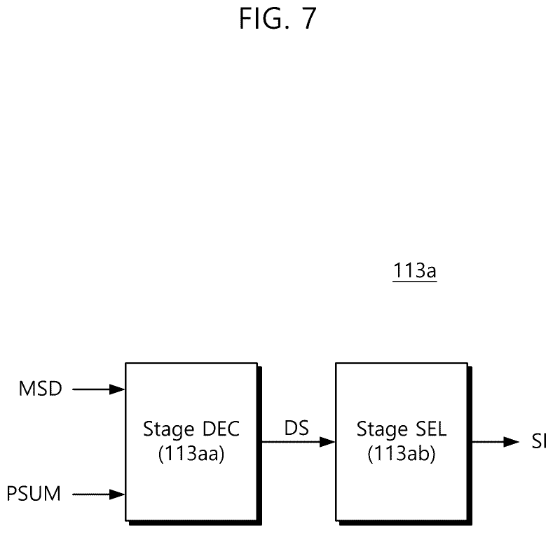

FIG. 6 is a diagram illustrating an example embodiment of a PIM operator of FIG. 4. FIG. 7 is a diagram illustrating an example embodiment of a stage manager of FIG. 6. Referring to FIGS. 6 and 7, the PIM operator 113 may include a stage manager 113a and a plurality of MAC operators (113_1, 113_2, 113_3, 113_4, . . . ). The stage manager 113a may include a stage decoder 113aa and a stage selector 113ab.

According to an example embodiment, the stage manager 113a may output a stage information signal SI based on a MAC operation completion signal MSD and a partial sum control signal PSUM. For example, the stage decoder 113aa may output a decoding signal DS based on the MAC operation completion signal MSD and the partial sum control signal PSUM. The stage selector 113ab may output the stage information signal SI based on the decoding signal DS.

According to an example embodiment, the plurality of MAC operators (113_1, 113_2, 113_3, 113_4, . . . ) may perform MAC operations in a MAC stage based on the stage information signal SI. When the MAC operation completion signal MSD is not received (or a low level of the MAC operation completion signal MSD is received), the stage manager 113a may output a stage information signal SI indicating the MAC stage (for example, a first stage information signal).

According to an example embodiment, when receiving a first stage information signal, the plurality of MAC operators (113_1, 113_2, 113_3, 113_4, . . . ) may operate in the MAC stage. For example, the first MAC operator 113_1 may perform a MAC operation on first MAC inputs Ma1 and Mb1 and output a first MAC result Mr1. The second MAC operator 113_2 may perform a MAC operation on second MAC inputs Ma2 and Mb2 and output a second MAC result Mr2. The third MAC operator 113_3 may perform a MAC operation on third MAC inputs Ma3 and Mb3 and output a third MAC result Mr3. The fourth MAC operator 113_4 may perform a MAC operation on fourth MAC inputs Ma4 and Mb4 and output a fourth MAC result Mr4.

According to an example embodiment, a plurality of MAC operators (113_1, 113_2, 113_3, 113_4, . . . ) may perform partial sum operations in a partial sum stage based on the stage information signal SI. When a MAC operation completion signal MSD is received (or a high level of the MAC operation completion signal MSD is received) and a partial sum control signal PSUM is received (or a high level of the partial sum control signal PSUM is received), the stage manager 113a may output a stage information signal SI (for example, a second stage information signal) indicating the partial sum stage.

According to an example embodiment, when receiving a second stage information signal, the plurality of MAC operators (113_1, 113_2, 113_3, 113_4, . . . ) may operate in the partial sum stage. For example, the first MAC operator 113_1 may perform a partial sum operation on first partial sum inputs Pa1 and Pb1 and output a first partial sum result Pr1. The second MAC operator 113_2 may perform a partial sum operation on second partial sum inputs Pa2 and Pb2 and output a second partial sum result Pr2. The third MAC operator 113_3 may perform a partial sum operation on third partial sum inputs Pa3 and Pb3 and output a third partial sum result Pr3. The fourth MAC operator 113_4 may perform a partial sum operation on fourth partial sum inputs Pa4 and Pb4 and output a fourth partial sum result Pr4.

According to an example embodiment, the plurality of MAC operators (113_1, 113_2, 113_3, 113_4, . . . ) may not perform partial sum operations after performing MAC operations based on a stage information signal SI. When a MAC operation completion signal MSD is received (or a high level of the MAC operation completion signal MSD is received) and a partial sum control signal PSUM is not received (or a low level of the partial sum control signal PSUM is received), the stage manager 113a may output a stage information signal SI (for example, a third stage information signal) indicating output of MAC operation results. When receiving a third stage information signal, the plurality of MAC operators (113_1, 113_2, 113_3, 113_4, . . . ) may output the MAC operation results without partial sum operations.

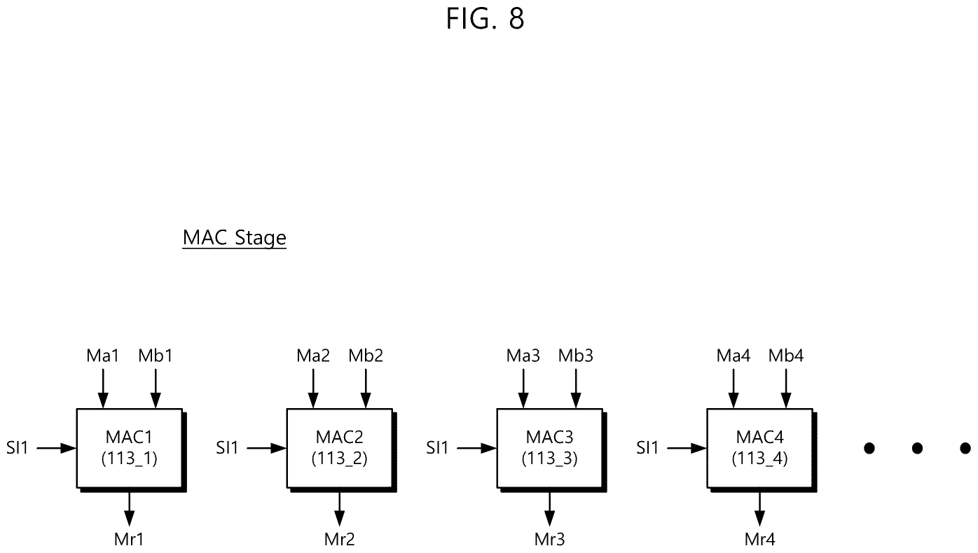

FIG. 8 is a diagram illustrating an operation of a plurality of MAC operators in FIG. 6 during a MAC stage according to an example embodiment. Referring to FIG. 8, the plurality of MAC operators (113_1, 113_2, 113_3, 113_4, . . . ) may perform MAC operations in a MAC stage based on a first stage information signal SI1.

According to an example embodiment, each of the plurality of MAC operators (113_1, 113_2, 113_3, 113_4, . . . ) may receive two MAC inputs and perform a MAC operation. For example, the first MAC operator 113_1 may perform a MAC operation on first MAC inputs Ma1 and Mb1 and output a first MAC result Mr1. The second MAC operator 113_2 may perform a MAC operation on second MAC inputs Ma2 and Mb2 and output a second MAC result Mr2. The third MAC operator 113_3 may perform a MAC operation on third MAC inputs Ma3 and Mb3 and output a third MAC result Mr3. The fourth MAC operator 113_4 may perform a MAC operation on fourth MAC inputs Ma4 and Mb4 and output a fourth MAC result Mr4.

According to an example embodiment, one of the MAC inputs received in one MAC operator may be data received from the memory cell array 1210 of FIG. 2. As an example, MAC inputs (Ma1, Ma2, Ma3, Ma4, . . . ) may be received from the memory cell array 1210.

According to an example embodiment, the other of the MAC inputs received in one MAC operator may be data stored in the PIM register file 112 of FIG. 4. As an example, MAC inputs (Mb1, Mb2, Mb3, Mb4, . . . ) may be received from the PIM register file 112.

According to an example embodiment, each of the plurality of MAC operators (113_1, 113_2, 113_3, 113_4, . . . ) may repeatedly perform the MAC operation based on the first stage information signal SI1. As an example, MAC results (Mr1, Mr2, Mr3, Mr4, . . . ) are transmitted as inputs to a portion of the plurality of MAC operators (113_1, 113_2, 113_3, 113_4, . . . ), and the MAC operation may be performed repeatedly.

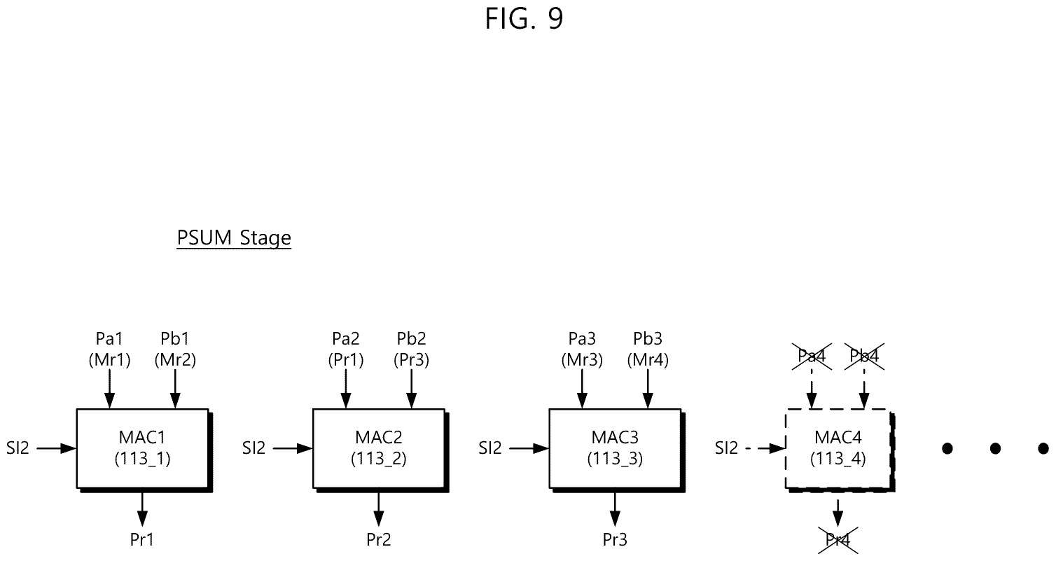

FIG. 9 is a diagram illustrating an operation during a partial sum stage of a plurality of MAC operators of FIG. 6 according to an example embodiment. Referring to FIG. 9, the plurality of MAC operators (113_1, 113_2, 113_3, 113_4, . . . ) may perform partial sum operations in a partial sum stage based on a second stage information signal SI2.

According to an example embodiment, the MAC results (Mr1, Mr2, Mr3, Mr4, . . . ) according to the MAC operations may be transmitted as inputs to a portion of the plurality of MAC operators (113_1, 113_2, 113_3, 113_4, . . . ). As an example, the first MAC result Mr1 generated by the first MAC operator 113_1 may be one partial sum input Pa1 of the first MAC operator 113_1. The second MAC result Mr2 generated by the second MAC operator 113_2 may be the other partial sum input Pb1 of the first MAC operator 113_1. In the partial sum stage, the first MAC operator 113_1 may perform a partial sum operation on the first MAC result Mr1 and the second MAC result Mr2 and output a first partial sum result Pr1.

As an example, the third MAC result Mr3 generated by the third MAC operator 113_3 may be one partial sum input Pa3 of the third MAC operator 113_3. The fourth MAC result Mr4 generated by the fourth MAC operator 113_4 may be the other partial sum input Pb3 of the third MAC operator 113_3. In the partial sum stage, the third MAC operator 113_3 may perform a partial sum operation on the third MAC result Mr3 and the fourth MAC result Mr4 and output a third partial sum result Pr3.

As an example, the first partial sum result Pr1 of the first MAC operator 113_1 may be one partial sum input Pa2 of the second MAC operator 113_2. The third partial sum result Pr3 by the third MAC operator 113_3 may be the other partial sum input Pb2 of the second MAC operator 113_2. In the partial sum stage, the second MAC operator 113_2 may perform a partial sum operation on the first partial sum result Pr1 and the third partial sum result Pr3 and output a second partial sum result Pr2.

According to an example embodiment, in the partial sum stage, a portion of the plurality of MAC operators (113_1, 113_2, 113_3, 113_4, . . . ) may repeatedly perform a partial sum operation. The partial sum results (Pr1, Pr2, Pr3, Pr4, . . . ) are transmitted as inputs to a portion of the plurality of MAC operators (113_1, 113_2, 113_3, 113_4, . . . ), and partial sum operations may be performed repeatedly. One of the plurality of MAC operators (113_1, 113_2, 113_3, 113_4, . . . may finally output one partial sum result. Accordingly, a plurality of MAC operators (113_1, 113_2, 113_3, 113_4, . . . ) may perform the role of the adder tree 20 of FIG. 5 in the partial sum stage. In the partial sum stage, a plurality of MAC operators (113_1, 113_2, 113_3, 113_4, . . . ) may produce the same effect or provide the same or similar functionality as the adder tree 20 of FIG. 5.

According to an example embodiment, in the partial sum stage, a portion of the plurality of MAC operators (113_1, 113_2, 113_3, 113_4, . . . ) may not be used. For example, the fourth MAC operator 113_4 may not operate in the partial sum stage because there is no input. As partial sum operations are repeated in the partial sum stage, the number of MAC operators used may decrease. Finally, one MAC operator may output a final partial sum result.

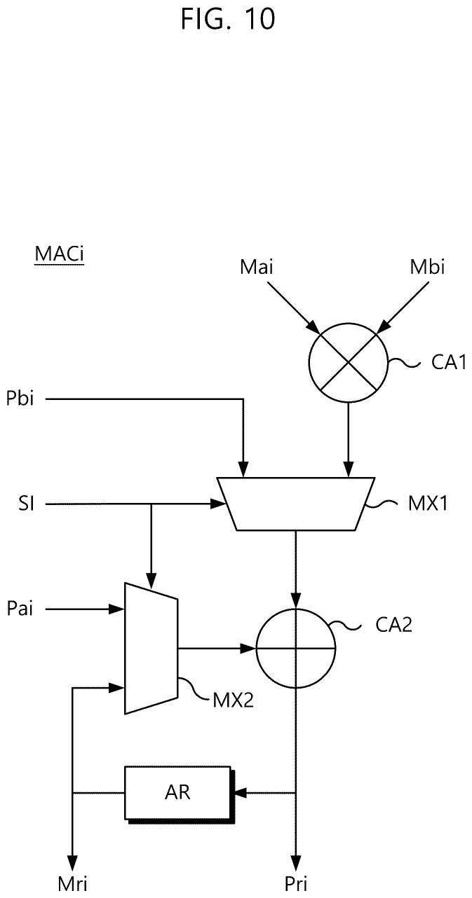

FIG. 10 is a diagram illustrating one of a plurality of MAC operators in FIG. 6 according to an example embodiment. Other ones of the plurality of MAC operators may be embodied similarly. Referring to FIG. 10, one MAC operator MACi may include a multiplier CA1, an adder CA2, an accumulation register AR, a first multiplexer MX1, and a second multiplexer MX2. The MAC operator MACi may perform a MAC operation on i-th MAC inputs Mai and Mbi, and output an i-th MAC result Mri. The MAC operator MACi may perform a partial sum operation on i-th partial sum inputs Pai and Pbi, and output an i-th partial sum result Pri.

According to an example embodiment, the MAC operator MACi may operate in a MAC stage or partial sum stage based on a stage information signal SI. For example, the first multiplexer MX1 may output an operation result of the multiplier CA1 or one (Pbi) of the i-th partial sum inputs Pai and Pbi based on the stage information signal SI. The second multiplexer MX2 may output one (Pai) of the i-th partial sum inputs Pai and Pbi or data stored in the accumulation register AR based on the stage information signal SI.

According to an example embodiment, in the MAC stage, the MAC operator MACi may perform a MAC operation on the i-th MAC inputs Mai and Mbi. For example, the first multiplexer MX1 may output an operation result of the multiplier CA1. The second multiplexer MX2 may output data stored in the accumulation register AR. An operation result of the adder CA2 may be stored in the accumulation register AR. During the MAC stage, the MAC operator MACi may repeatedly perform MAC operations through the multiplier CA1, the adder CA2, and the accumulation register AR.

According to an example embodiment, in the partial sum stage, the MAC operator MACi may perform a partial sum operation on the i-th partial sum inputs Pai and Pbi. For example, the first multiplexer MX1 may output one (Pbi) of the i-th partial sum inputs Pai and Pbi. The second multiplexer MX2 may output one (Pai) of the i-th partial sum inputs Pai and Pbi. An operation result of the adder CA2 may be output as the i-th partial sum result Pri.

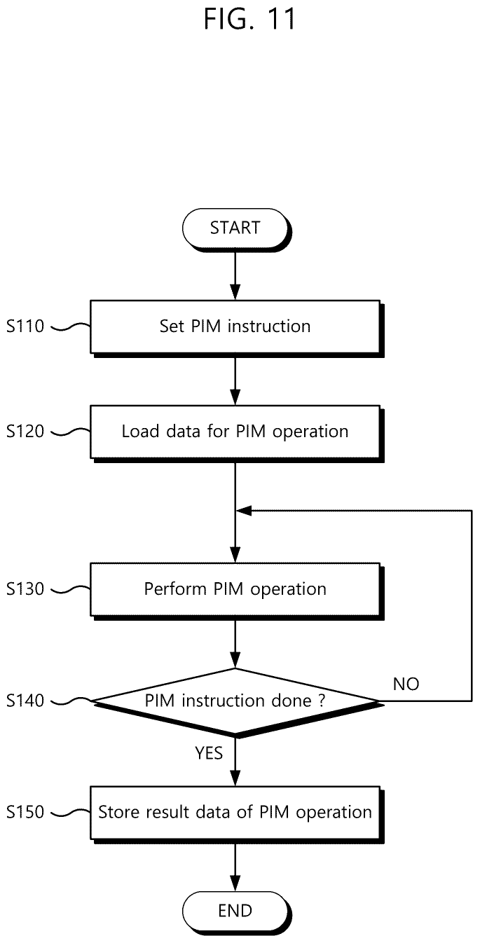

FIG. 11 is a flowchart illustrating a PIM operation of a PIM unit of FIG. 2. Referring to FIGS. 2 to 11, the memory device 1200 may perform a PIM operation based on a command CMD or an address ADDR received from the memory controller 1100 of FIG. 1.

According to an example embodiment, in operation S110, the memory device 1200 may set one or more PIM instructions. For example, the memory device 1200 may perform a PIM operation when receiving a general command CMD and a specified address ADDR for the PIM operation. In other embodiments, the memory device 1200 may perform a PIM operation when receiving a specified command CMD for the PIM operation.

According to an example embodiment, when an address ADDR or a command CMD for a PIM operation is received, the control logic 1250 may activate the PIM unit 100. The PIM unit 100 may set a PIM instruction under the control of the control logic 1250. The PIM execution unit 110 may read the PIM instruction from the PIM register 120.

According to an example embodiment, in operation S120, the memory device 1200 may load data for the PIM operation. For example, the PIM execution unit 110 may load first data from the memory cell array 1210. The PIM execution unit 110 may receive second data from the PIM register 120. The PIM control logic 111 may store the first data and the second data in the PIM register file 112.

According to an example embodiment, in operation S130, the memory device 1200 may perform a PIM operation. For example, the PIM execution unit 110 may perform the PIM operation based on the first data and the second data. The PIM control logic 111 may perform the PIM operation on the first data and the second data through the PIM operator 113.

According to an example embodiment, in operation S140, the memory device 1200 may confirm whether the PIM instruction is completed. For example, the PIM control logic 111 may check whether all set PIM instructions have been completed. When all PIM instructions are completed, the PIM control logic 111 may perform operation S150. When there is at least a remaining uncompleted PIM instruction, the PIM control logic 111 may repeatedly perform operations S130 and S140.

According to an example embodiment, in operation S150, the memory device 1200 may store result data of the PIM operation. For example, the PIM control logic 111 may store the result data of the PIM operation in the PIM register file 112. The PIM execution unit 110 may transmit the result data of the PIM operation to the memory cell array 1210 or the input/output circuit 1260.

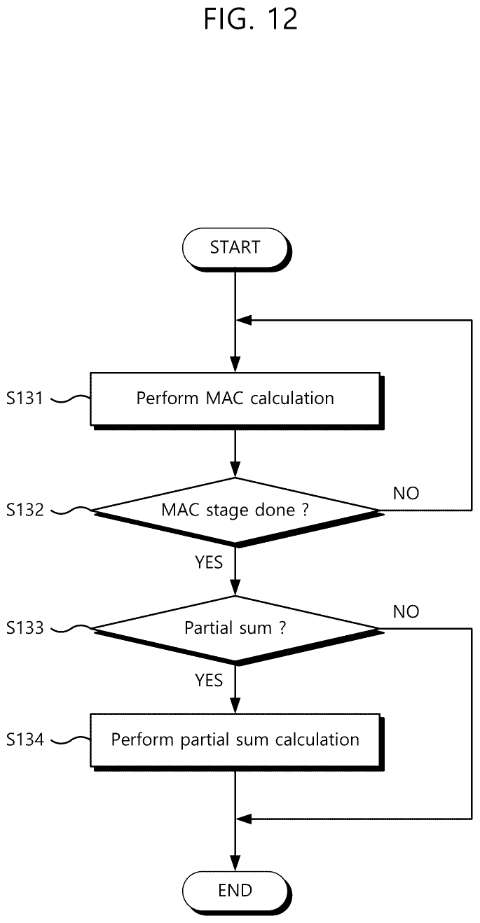

FIG. 12 is a flowchart illustrating a method of performing a PIM operation of FIG. 11. Referring to FIGS. 2 to 12, the PIM unit 100 may perform a PIM operation through the plurality of MAC operators (113_1, 113_2, 113_3, 113_4, . . . ).

According to an example embodiment, in operation S131, the PIM unit 100 may perform a MAC operation. For example, the PIM control logic 111 may transmit a MAC operation start signal to the PIM operator 113. The PIM operator 113 may start the MAC operation based on the MAC operation start signal. As an example, the plurality of MAC operators (113_1, 113_2, 113_3, 113_4, . . . ) may be set to a MAC stage based on the MAC operation start signal. Each of the plurality of MAC operators (113_1, 113_2, 113_3, 113_4, . . . ) may perform the MAC operation based on first data and second data.

According to an example embodiment, in operation S132, the PIM unit 100 may confirm whether the MAC operation is complete. For example, the stage manager 113a may check whether the MAC operation completion signal MSD is received. The plurality of MAC operation units (113_1, 113_2, 113_3, 113_4, . . . ) may output a MAC operation completion signal MSD when the MAC operation is completed.

For example, when the MAC operation completion signal MSD is not received (or when a low level of the MAC operation completion signal MSD is received), the stage manager 113a may output a stage information signal SI indicating a MAC stage (for example, a first stage information signal). At this time, the PIM unit 100 may repeat the operations S131 and S132. When receiving the MAC operation completion signal MSD (or receiving a high level of the MAC operation completion signal MSD), the stage manager 113a may perform operation S133.

According to an example embodiment, in operation S133, the PIM unit 100 may confirm whether a partial sum operation is performed. For example, the stage manager 113a may check whether a MAC operation completion signal MSD and a partial sum control signal PSUM are received.

As an example, the MAC operation completion signal MSD is received (or a high level of the MAC operation completion signal MSD is received) and the partial sum control signal PSUM is received (or a high level of the partial sum control signal PSUM is received), the stage manager 113a may output a stage information signal SI (for example, a second stage information signal) indicating a partial sum stage. At this time, the PIM unit 100 may perform operation S134.

As an example, when a MAC operation completion signal MSD is received (or a high level of the MAC operation completion signal MSD is received) and a partial sum control signal PSUM is not received (or a low level of the partial sum control signal PSUM), the stage manager 113a may output a stage information signal SI (for example, a third stage information signal) indicating output of a MAC operation result. When receiving the third stage information signal, the plurality of MAC operators (113_1, 113_2, 113_3, 113_4, . . . ) may output MAC operation results without partial sum operations.

According to an example embodiment, in operation S134, the PIM unit 100 may perform a partial sum operation. For example, when receiving a second stage information signal, the plurality of MAC operators (113_1, 113_2, 113_3, 113_4, . . . ) may operate in a partial sum stage. As an example, the first MAC operator 113_1 may perform a partial sum operation on first partial sum inputs Pa1 and Pb1 and output a first partial sum result Pr1. The second MAC operator 113_2 may perform a partial sum operation on second partial sum inputs Pa2 and Pb2 and output a second partial sum result Pr2. The third MAC operator 113_3 may perform a partial sum operation on third partial sum inputs Pa3 and Pb3 and output a third partial sum result Pr3. The fourth MAC operator 113_4 may perform a partial sum operation on fourth partial sum inputs Pa4 and Pb4 and output a fourth partial sum result Pr4.

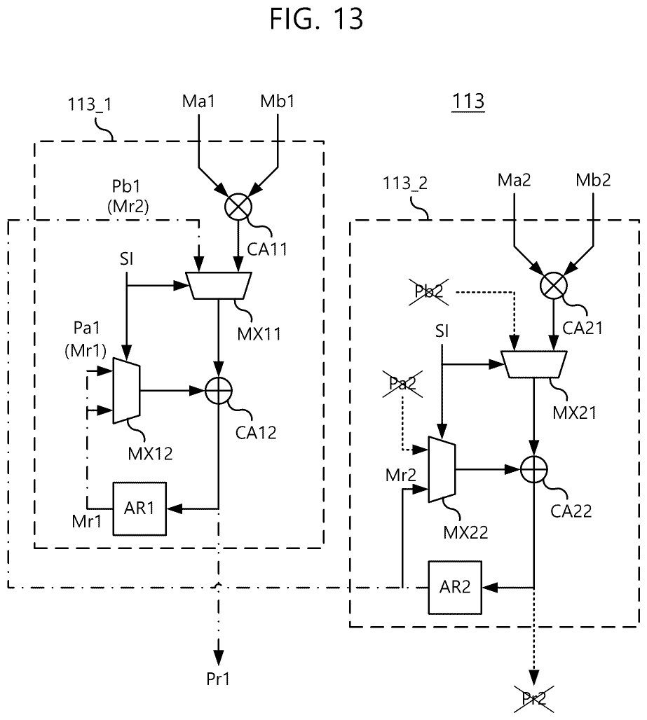

FIG. 13 is a diagram illustrating an example embodiment of a wiring layout of a plurality of MAC operators in FIG. 6. FIG. 13 illustrates an example in which a partial sum operation is performed using two MAC operators according to an embodiment. Referring to FIG. 13, the first MAC operator 113_1 may receive first MAC inputs (Ma1, Mb1) and first partial sum inputs (Pa1, Pb1), and output a first MAC result Mr1 and a first partial sum result Pr1. The second MAC operator 113_2 may receive second MAC inputs (Ma2, Mb2) and second partial sum inputs (Pa2, Pb2), and output a second MAC result Mr2 and a second partial sum result Pr2.

According to an example embodiment, in a partial sum stage, the first MAC operator 113_1 may perform a partial sum operation of the first MAC result Mr1 and the second MAC result Mr2. For example, a first accumulation register AR1 may output the first MAC result Mr1. The first MAC result Mr1 may be transmitted to the first-a partial sum input Pa1. The second MAC result Mr2 may be transmitted to the first-b partial sum input Pb1. In the partial sum stage, the first MAC operator 113_1 may perform a partial sum operation, and the second MAC operator 113_2 may be deactivated.

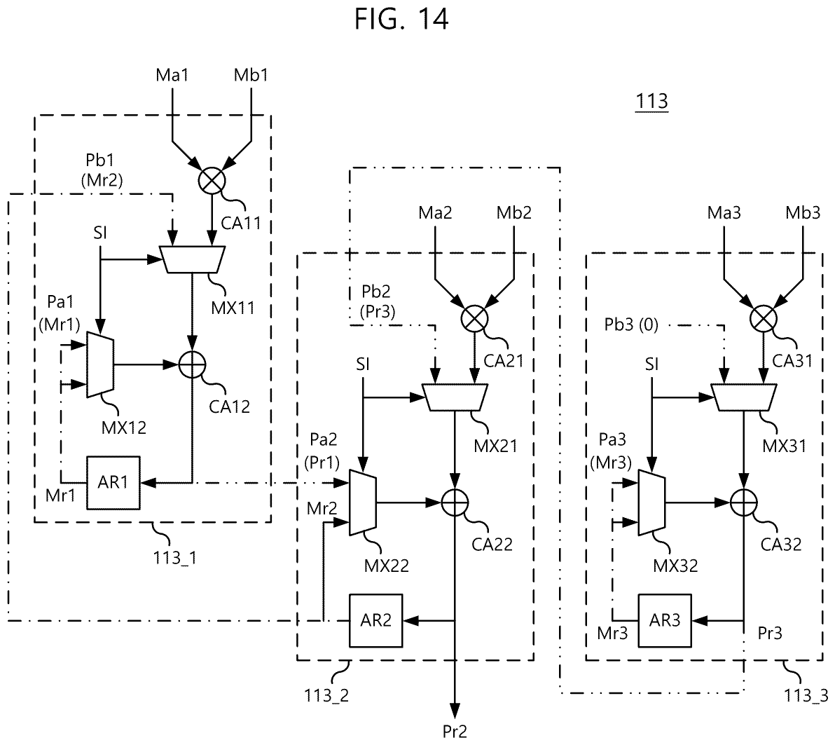

FIG. 14 is a diagram illustrating another example embodiment of a wiring layout of a plurality of MAC operators in FIG. 6. FIG. 14 illustrates an example in which a partial sum operation is performed using three MAC operators according to an embodiment. Referring to FIG. 14, the first MAC operator 113_1 may receive first MAC inputs (Ma1, Mb1) and first partial sum inputs (Pa1, Pb1), and output a first MAC result Mr1 and a first partial sum result Pr1. The second MAC operator 113_2 may receive second MAC inputs (Ma2, Mb2) and second partial sum inputs (Pa2, Pb2), and output a second MAC result Mr2 and a second partial sum result Pr2. The third MAC operator 113_3 may receive third MAC inputs (Ma3, Mb3) and third partial sum inputs (Pa3, Pb3), and output a third MAC result Mr3 and a third partial sum result Pr3.

According to an example embodiment, in the partial sum stage, the first MAC operator 113_1 may perform a partial sum operation of the first MAC result Mr1 and the second MAC result Mr2. For example, a first accumulation register Mr1 may output the first MAC result Mr1. The first MAC result Mr1 may be transmitted to the first-a partial sum input Pa1. The second MAC result Mr2 may be transmitted to the first-b partial sum input Pb1. The first MAC operator 113_1 may output a first partial sum result Pr1.

According to an example embodiment, in the partial sum stage, the third MAC operator 113_3 may output the third MAC result Mr3 intactly. For example, a third accumulation register AR3 may output the third MAC result Mr3. The third MAC result Mr3 may be transmitted to the third partial sum input Pa3. Logic 0 may be input to the third-b partial sum input Pb3. The third MAC operator 113_3 may output the third MAC result Mr3 as the third partial sum result Pr3.

According to an example embodiment, in the partial sum stage, the second MAC operator 113_2 may perform a partial sum operation of the first partial sum result Pr1 and the third partial sum result Pr3. For example, the first partial sum result Pr1 may be transmitted to the second-a partial sum input Pa2. The third partial sum result Pr3 may be transmitted to the second-b partial sum input Pb2. The second MAC operator 113_2 may output the second partial sum result Pr2.

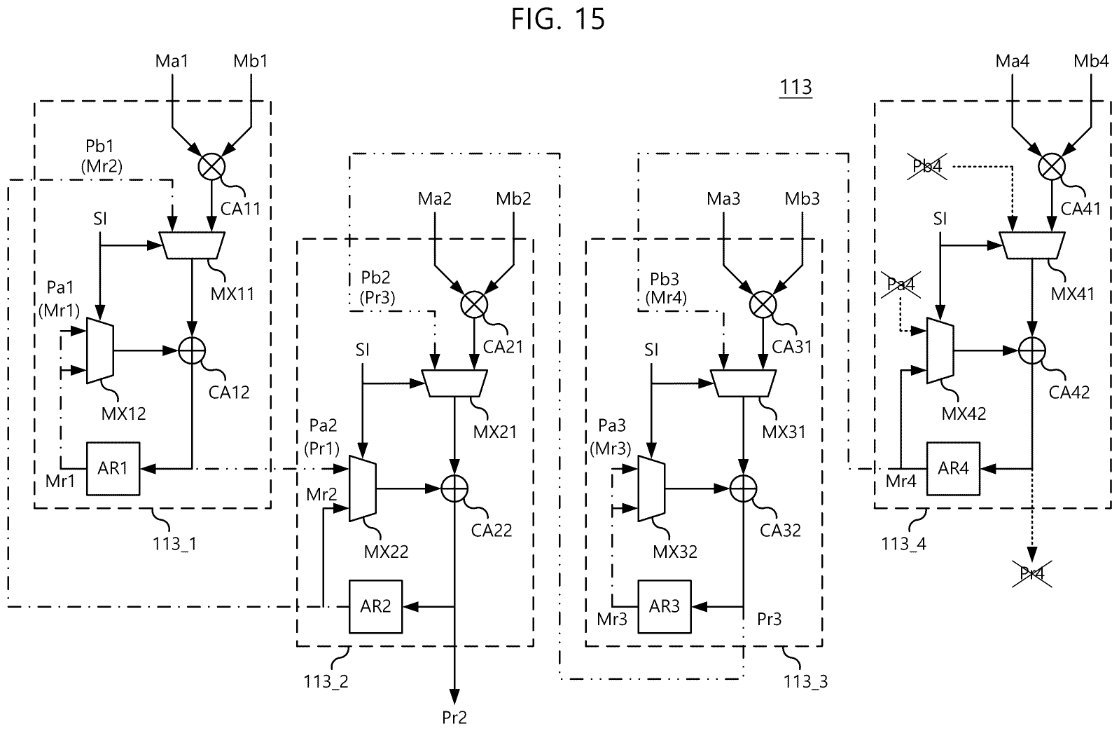

FIG. 15 is a diagram illustrating another example embodiment of a wiring layout of a plurality of MAC operators in FIG. 6. FIG. 15 illustrates an example in which a partial sum operation is performed using four MAC operators according to an example embodiment. Referring to FIG. 15, the first MAC operator 113_1 may receive first MAC inputs (Ma1, Mb1) and first partial sum inputs (Pa1, Pb1), and output a first MAC result Mr1 and a first partial sum result Pr1. The second MAC operator 113_2 may receive second MAC inputs (Ma2, Mb2) and second partial sum inputs (Pa2, Pb2), and output a second MAC result Mr2 and a second partial sum result Pr2. The third MAC operator 113_3 may receive third MAC inputs (Ma3, Mb3) and third partial sum inputs (Pa3, Pb3), and output a third MAC result Mr3 and a third partial sum result Pr3. The fourth MAC operator 113_4 may receive fourth MAC inputs (Ma4, Mb4) and fourth partial sum inputs (Pa4, Pb4), and a fourth MAC result Mr4 and a fourth partial sum result Pr4.

According to an example embodiment, in a partial sum stage, the first MAC operator 113_1 may perform a partial sum operation of the first MAC result Mr1 and the second MAC result Mr2. For example, a first accumulation register AR1 may output the first MAC result Mr1. The first MAC result Mr1 may be transmitted to a first-a partial sum input Pa1. The second MAC result Mr2 may be transmitted to a first-b partial sum input Pb1. The first MAC operator 113_1 may output the first partial sum result Pr1.

According to an example embodiment, in the partial sum stage, the third MAC operator 113_3 may perform a partial sum operation of the third MAC result Mr3 and the fourth MAC result Mr4. For example, a third accumulation register AR3 may output the third MAC result Mr3. The third MAC result Mr3 may be transmitted to the third-a partial sum input Pa3. The fourth accumulation register Mr4 may output the fourth MAC result Mr4. The fourth MAC result Mr4 may be transmitted to the third-b partial sum input Pb3. The third MAC operator 113_3 may output the third partial sum result Pr3.

According to an example embodiment, in the partial sum stage, the second MAC operator 113_2 may perform a partial sum operation of the first partial sum result Pr1 and the third partial sum result Pr3. For example, the first partial sum result Pr1 may be transmitted to the second-a partial sum input Pa2. The third partial sum result Pr3 may be transmitted to the second-b partial sum input Pb2. The second MAC operator 113_2 may output the second partial sum result Pr2.

According to embodiments of the present disclosure, it may be possible to reduce the area required for an adder tree as MAC operations and partial sum operations are performed by using a plurality of MAC operators included in the PIM unit.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. A memory device comprising:
a memory cell array; and
a processing in memory (PIM) unit including a plurality of multiplication and accumulation (MAC) operators which is configured to perform multiply-accumulation operations based on data stored in the memory cell array,
wherein the plurality of MAC operators is configured to perform the multiply-accumulation operations based on the data in a first stage, and to perform partial sum operations based on result values of the multiply-accumulation operations in a second stage.

2. The memory device of claim 1, wherein each of the plurality of MAC operators comprises:
a multiplier configured to perform a multiplication operation using a first MAC input and a second MAC input as operands;
a first multiplexer configured to output a first operation result from the multiplier or a first partial sum input based on a stage information signal;
a second multiplexer configured to output a second partial sum input or data stored in an accumulation register based on the stage information signal; and
an adder configured to perform an addition operation on a first output of the first multiplexer and a second output of the second multiplexer,
wherein a second operation result output from the adder is stored in the accumulation register.

3. The memory device of claim 2, wherein the stage information signal comprises a first stage information signal;
wherein the first multiplexer is configured to output the first operation result based on the first stage information signal corresponding to the first stage,
wherein the second multiplexer is configured to output data stored in the accumulation register based on the first stage information signal,
wherein the adder is configured to store the second operation result in the accumulation register, and
wherein the accumulation register is configured to output the second operation result as a multiply-accumulation operation result.

4. The memory device of claim 2, wherein the stage information signal comprises a second stage information signal;
wherein the first multiplexer is configured to output the first partial sum input based on the second stage information signal corresponding to the second stage,
wherein the second multiplexer is configured to output the second partial sum input based on the second stage information signal, and
wherein the adder is configured to output the second operation result as a partial sum operation result.

5. The memory device of claim 1, wherein the plurality of MAC operators includes a first MAC operator and a second MAC operator,
wherein the first MAC operator is configured to perform a multiply-accumulation operation using a first MAC input and a second MAC input as operands in the first stage to output a first MAC result, and
wherein the second MAC operator is configured to perform a multiply-accumulation operation using a third MAC input and a fourth MAC input as operands in the first stage to output a second MAC result.

6. The memory device of claim 5, wherein the first MAC operator is configured to perform a partial sum operation of the first MAC result and the second MAC result in the second stage.

7. The memory device of claim 1, wherein the plurality of MAC operators includes a first MAC operator, a second MAC operator, and a third MAC operator,
wherein the first MAC operator is configured to perform a multiply-accumulation operation using a first MAC input and a second MAC input as first operands in the first stage to output a first MAC result,
wherein the second MAC operator is configured to perform a multiply-accumulation operation using a third MAC input and a fourth MAC input as second operands in the first stage to output a second MAC result, and
wherein the third MAC operator is configured to perform a multiply-accumulation operation using a fifth MAC input and a sixth MAC input as third operands in the first stage to output a third MAC result.

8. The memory device of claim 7, wherein the first MAC operator is configured to perform a partial sum operation of the first MAC result and the second MAC result in the second stage to output a first partial sum result,
wherein the second MAC operator is configured to perform a partial sum operation of the third MAC result and logical 0 in the second stage to output a second partial sum result, and
wherein the third MAC operator is configured to perform a partial sum operation of the first partial sum result and the second partial sum result in the second stage.

9. The memory device of claim 1, wherein the plurality of MAC operators is configured to include a first MAC operator, a second MAC operator, a third MAC operator, and a fourth MAC operator,
wherein the first MAC operator is configured to perform a multiply-accumulation operation using a first MAC input and a second MAC input as first operands in the first stage to output a first MAC result,
wherein the second MAC operator is configured to perform a multiply-accumulation operation using a third MAC input and a fourth MAC input as second operands in the first stage to output a second MAC result,
wherein the third MAC operator is configured to perform a multiply-accumulation operation using a fifth MAC input and a sixth MAC input as third operands in the first stage to output a third MAC result, and
wherein the fourth MAC operator is configured to perform a multiply-accumulation operation using a seventh MAC input and an eighth MAC input as fourth operands in the first stage to output a fourth MAC result.

10. The memory device of claim 9, wherein the first MAC operator is configured to perform a partial sum operation of the first MAC result and the second MAC result in the second stage to output a first partial sum result,
wherein the second MAC operator is configured to perform a partial sum operation of the third MAC result and the third MAC result in the second stage to output a second partial sum result,
wherein the third MAC operator is configured to perform a partial sum operation of the first partial sum result and the second partial sum result in the second stage, and
wherein the fourth MAC operator is configured to be inactive in the second stage.

11. The memory device of claim 1, further comprising:
a stage manager configured to generate a stage information signal which determines the first stage or the second stage.

12. The memory device of claim 11, wherein the stage manager is further configured to generate a first stage information signal corresponding to the first stage or a second stage information signal corresponding to the second stage based on a MAC operation completion signal received from the plurality of MAC operators and a partial sum control signal received from the PIM unit.

13. A method of performing processing in memory of a memory device, the method comprising:
setting up one or more processing in memory (PIM) instructions;
loading first data for a PIM operation from a memory cell array of the memory device based on the one or more PIM instructions; and
performing the PIM operation based on the first data,
wherein the performing the PIM operation includes:
performing multiply-accumulation operations on the first data through a plurality of MAC operators in a first stage; and
performing partial sum operations based on result values of the multiply-accumulation operations in a second stage when the multiply-accumulation operations are completed.

14. The method of claim 13, wherein the performing of the multiply-accumulation operations includes performing a multiply-accumulation operation on two MAC inputs in each of the plurality of MAC operators, respectively, to output a MAC result.

15. The method of claim 14, wherein the performing of the partial sum operations includes inputting the MAC results from the plurality of MAC operators into a first portion of the plurality of MAC operators to output partial sum operation results.

16. The method of claim 15, wherein the performing of the partial sum operations further includes inputting the partial sum operation results into a second portion of the plurality of MAC operators to finally output one partial sum operation result.

17. A memory device comprising:
a memory cell array;
control logic configured to control input and output of data to and from, respectively, the memory cell array; and
a plurality of MAC operators configured to perform multiply-accumulation operations based on data stored in the memory cell array responsive to a MAC operation start signal received from the control logic,
wherein each of the plurality of MAC operators includes:
a multiplier configured to perform a multiplication operation using a first MAC input and a second MAC input as operands;
a first multiplexer configured to output a first operation result of the multiplier or a first partial sum input based on a stage information signal;
a second multiplexer configured to output a second partial sum input or data stored in an accumulation register based on the stage information signal; and
an adder configured to perform an addition operation on a first output of the first multiplexer and a second output of the second multiplexer.

18. The memory device of claim 17, wherein the first multiplexer and the second multiplexer are configured to receive a first stage information signal during a first stage,
wherein the first multiplexer is further configured to output the first operation result based on the first stage information signal,
wherein the second multiplexer is further configured to output data stored in the accumulation register based on the first stage information signal,
wherein the adder is further configured to store a second operation result in the accumulation register, and
wherein the accumulation register is configured to output the second operation result as a multiply-accumulation operation result.

19. The memory device of claim 18, wherein the first multiplexer and the second multiplexer are configured to receive a second stage information signal during a second stage,
wherein the first multiplexer is further configured to output the first partial sum input based on the second stage information signal,
wherein the second multiplexer is further configured to output the second partial sum input based on the second stage information signal, and
wherein the adder is further configured to output the second operation result as a partial sum operation result.

20. The memory device of claim 17, wherein the first multiplexer and the second multiplexer are configured to be inactive responsive to receiving a third stage information signal.
